(19) United States
(12) Patent Application Publication
(10) Pub. No.: US 2019/0382260 A1
(43) Pub. Date: Dec. 19, 2019

(54) LOW COST WAFER BONDING METHOD

(71) Applicant: Innovative Micro Technology, Goleta, CA (US)

(72) Inventor: Jeffery F. SUMMERS, Santa Barbara, CA (US)

(73) Assignee: Innovative Micro Technology, Goleta, CA (US)

(21) Appl. No.: 16/433,357

(22) Filed: Jun. 6, 2019

Related U.S. Application Data
(60) Provisional application No. 62/684,691, filed on Jun. 13, 2018.

(51) Int. Cl. B81C 1/00; B32B 7/12; B32B 18/00; B32B 37/12; B81B 7/00

(52) U.S. Cl. CPC B81C 1/00238; B32B 7/12; B32B 18/00; B81C 2203/032; B81B 7/008; B32B 2457/14; B32B 37/12

(57) ABSTRACT

The invention is directed to an inexpensive method for bonding two wafers. The method uses an adhesive material disposed between two handling sheets and stamped with a plurality of through holes. The through holes are registered with the locations of devices formed on a substrate. The adhesive material is placed between to two substrates, around the devices, and cured.

### CROSS REFERENCE TO RELATED APPLICATIONS

This US Nonprovisional patent application claims priority to U.S. Provisional Patent Application Ser. No. 62/684,691, filed Jun. 13, 2018, which is incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

The present invention is directed to a method for adhering a first substrate to a second substrate, in order to enclose microfabricated devices in device cavities formed on the substrates.

Microelectromechanical systems (MEMS) are devices often having moveable components which are manufactured using lithographic fabrication processes developed for producing semiconductor electronic devices. Because the manufacturing processes are lithographic, MEMS devices may be batch fabricated in very small sizes. MEMS techniques have been used to manufacture a wide variety of sensors and actuators, such as accelerometers and electrostatic cantilevers.

MEMS techniques have also been used to manufacture electrical relays or switches of small size, generally using an electrostatic actuation means to activate the switch. MEMS devices often make use of silicon-on-insulator (SOI) device wafers, which are a relatively thick silicon “handle” wafer with a thin silicon dioxide insulating layer, followed by a relatively thin silicon “device” layer. In the MEMS switches, a thin cantilevered beam of silicon is etched into the silicon device layer, and a cavity is created adjacent to the cantilevered beam, typically by etching the thin silicon dioxide layer to allow for the electrostatic deflection of the beam. Electrodes provided above or below the beam may provide the voltage potential which produces the attractive (or repulsive) force to the cantilevered beam, causing it to deflect within the cavity.

Because the MEMS devices often have moveable components, such as the cantilevered beam, they typically require protection of the moveable portions by sealing the devices in a protective cap or lid wafer, to form a device cavity. The lid wafer may be secured to the device wafer by some adhesive means, such as a layer of malleable material, which, when compressed, may form a thermocompression bond with material on the opposing substrate. To achieve the thermocompression bond, a layer of, for example, gold (Au) may be deposited on a cap or lid wafer, or on the fabrication wafer, around the perimeter of the MEMS device. The assembly is then heated and the lid wafer pressed against the fabrication wafer, until a bond is formed between the cap or lid wafer and the fabrication wafer. The thermocompression bond forms a device cavity which surrounds the MEMS device. The assembly may then be diced to separate the individual MEMS devices. This thermocompression bond may be hermetic (non-leaking) seal, to enclose the device in a defined environment.

However, the gold may be deposited lithographically, requiring an evacuated environment and clean room procedures, which is generally quite expensive. Not all devices require hermetic sealing. Accordingly, what is needed is a cheaper, wafer-level bonding methodology which is not necessarily hermetic.

### SUMMARY

The method disclosed here uses an adhesive such as a hot melt glue to bond a first substrate to a second substrate. A plurality of microdevices may be fabricated on at least one of the first and the second substrates. A plurality of device cavities may be formed in the other substrate.

The adhesive may be disposed between two handling sheets. The handling sheets do not adhere well to the adhesive, and ma thus be readily peeled off or otherwise removed. The handling sheets allow the adhesive to be handled easily. Accordingly, the adhesive disposed between the handling sheets may define an adhesive structure or adhesive “wafer”, because it may be chosen to have the same or similar dimensions as the first substrate and second substrate or semiconductor wafer.

The adhesive wafer may be stamped to form through holes in the adhesive wafer. These holes may penetrate through the entire adhesive wafer, including the handling sheets. The through holes may be registered with the plurality of devices and device cavities.

Upon first removing one of the two handling sheets, the adhesive sheet may be deployed on the first substrate, and tacked thereto with heat sufficient to cause the adhesive to at least loosely adhere to the first substrate surface. The second handling sheet may then be removed and the second substrate pressed against the adhesive material on the first substrate. The adhesive is then heated to melt and/or cure the adhesive, bonding the second substrate to the first substrate. Upon cooling, the first substrate is bonded to the second substrate with a firm bond.

Accordingly, a method for bonding two substrates with an adhesive material is disclosed. The method may include providing a sheet of adhesive material between two adhering handling sheets, forming through holes through the adhesive material and the adhering handling sheets, wherein the through holes are located at positions corresponding to structures formed in a first substrate, and removing one of the sheets to expose a surface of the adhesive material and tacking the adhesive material to the first substrate at the exposed surface. The method may further include, removing the second sheet to expose an obverse surface of the adhesive material, disposing a second substrate on the exposed obverse surface of the adhesive material to form a stack of two substrates and the adhesive material, and bonding a second substrate to the first substrate by applying heat and pressure to the stack.

### BRIEF DESCRIPTION OF THE DRAWINGS

FIG. 1 is a simplified cross sectional illustration of the low cost bonding method at the first step, wherein an adhesive material is sandwiched between two handling sheets;

FIG. 2 is a simplified cross sectional illustration of the low cost bonding method at the second step, wherein through holes are formed in the adhesive material and two handling sheets;

FIG. 3 is a simplified cross sectional illustration of the low cost bonding method at the third step, wherein one of the handling sheets is removed;

FIG. 4 is a simplified cross sectional illustration of the low cost bonding method at the fourth step, wherein the adhesive material is aligned to a first substrate, such that the through holes in the adhesive material are registered with features on the substrate;

FIG. 5 is a simplified cross sectional illustration of the low cost bonding method at the fifth step, wherein the adhesive material is tacked to the first substrate;

FIG. 6 is a simplified cross sectional illustration of the low cost bonding method at the sixth step, wherein the second handling sheet is removed from the adhesive material;

FIG. 7 is a simplified cross sectional illustration of the low cost bonding method at the seventh step, wherein a second substrate is aligned against the adhesive material and the first substrate with features in the second substrate registered with the through holes in the adhesive material; and

FIG. 8 is a simplified cross sectional illustration of the low cost bonding method at the eighth step, wherein the second substrate is pressed against the adhesive material and the first substrate such that the first and the second substrate are bonded in place.

It should be understood that the drawings are not necessarily to scale, and that like numbers may refer to like features.

### DETAILED DESCRIPTION

The following discussion presents a plurality of exemplary embodiments of the low cost wafer bonding method. It should be understood that the term “wafer” and “substrate” are used interchangeably herein. Both denote a generally circular, flat surface, on which devices are fabricated using photolithographic methods. The following reference numbers are used in the accompanying figures to refer to the following:
10 top handling sheet
20 adhesive material
25 through holes
30 bottom handling sheet
50 device substrate
55 device
20 adhesive material
40 lid substrate
45 device cavity

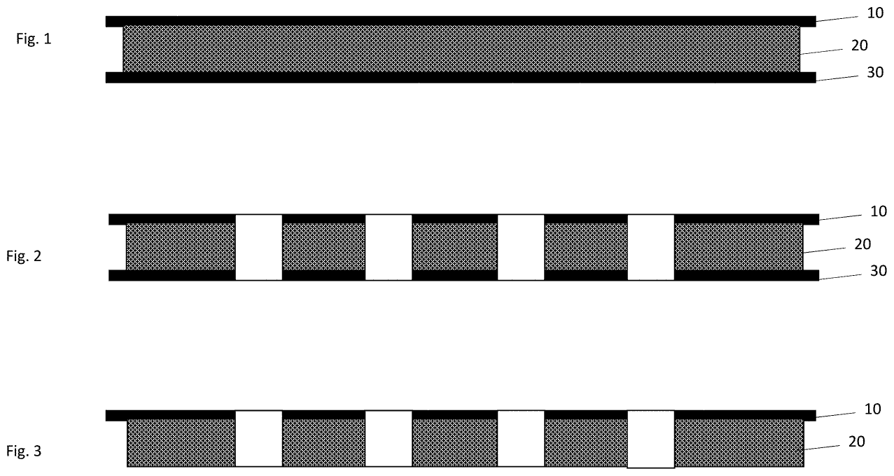

FIG. 1 is a simplified cross sectional illustration of the low cost bonding method at the first step, showing the low cost adhesive structure. The adhesive structure may be an adhesive material 20 is sandwiched between two handling sheets a top handling sheet 10, and a bottom handling sheet 30. This configuration of adhesive and handling sheets may be referred to herein as an adhesive structure or adhesive “wafer” in reference to its dimensional similarity to the substrates 40 and 50 in some embodiments. However, in other embodiments, the adhesive structure need not necessarily be circular.

The handling sheets 10, 30 may be non-interactive with the adhesive material 20, such that they are removably and temporarily in contact with the adhesive material. Accordingly, the handling sheets 10, 30 may be an absorptive material like non-adhesive paper with a waxy coating that forms a loosely adhered barrier and handling structure. Other alternatives are a flexible silicone material or a neoprene or synthetic rubber.

The adhesive material 20 may be, for example, a phenolic nitrile layer between 2 mils and 50 microns thick. In some embodiments, the adhesive may be a hot melt glue.

FIG. 2 is a simplified cross sectional illustration of the low cost bonding method at the second step, wherein through holes 25 are formed in the adhesive structure, through the adhesive material 20 and two handling sheets 10, 30. The holes may be formed mechanically in the adhesive structure by, for example, punching or stamping. The holes may also be formed photolithographically.

In an alternative embodiment, the adhesive can be rolled onto the substrate by a hot roller machine for the adhesive. The wafer is passed over the hot roller that is picking up the adhesive from a tray. The adhesive-coated roller then puts adhesive on the high spots on the wafer.

FIG. 3 is a simplified cross sectional illustration of the low cost bonding method at the third step, wherein one of the handling sheets is removed. The bottom handling sheet 30 may be removed by peeling the material away from a corner, and then over the entire surface of the adhesive structure. This operation my be done by hand or robotically, for example.

FIG. 4 is a simplified cross sectional illustration of the low cost bonding method at the fourth step, wherein the adhesive material 20 is aligned to a first substrate 40, such that the through holes 25 in the adhesive material are registered with features on the first substrate 40. The substrate may be a silicon substrate. In other embodiments, the substrate may be glass, ceramic, quartz, oxides, metals or other semiconductor materials.

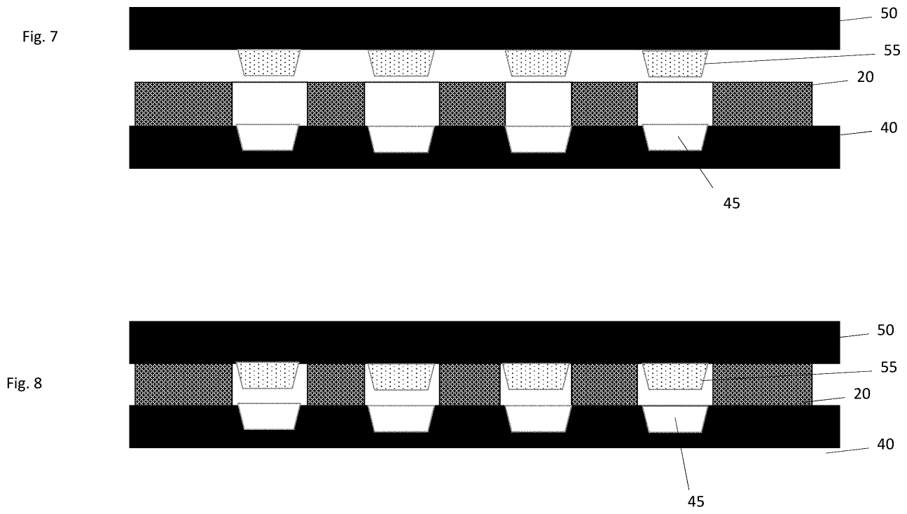

The first substrate 40 may have device cavities 45 formed thereon, with a given pitch between each of the device cavities. Device cavities are often on the order of 600 microns wide, with 400 micron lands in between these spaces. These 400 micron lands are sufficient for saw cutting, dicing, or otherwise singulating the individual devices 55 (see FIG. 7). Accordingly, these through holes 25 may be registered with the devices 55 or the device cavities 45 or both.

For relatively large alignment tolerances as would be used, for example, with large features and devices, the alignment between the through holes 25 and the device cavities 45 may be done by hand. For more precise alignment tolerances, the alignment may be done by stepper motors and/or translation stages, for example.

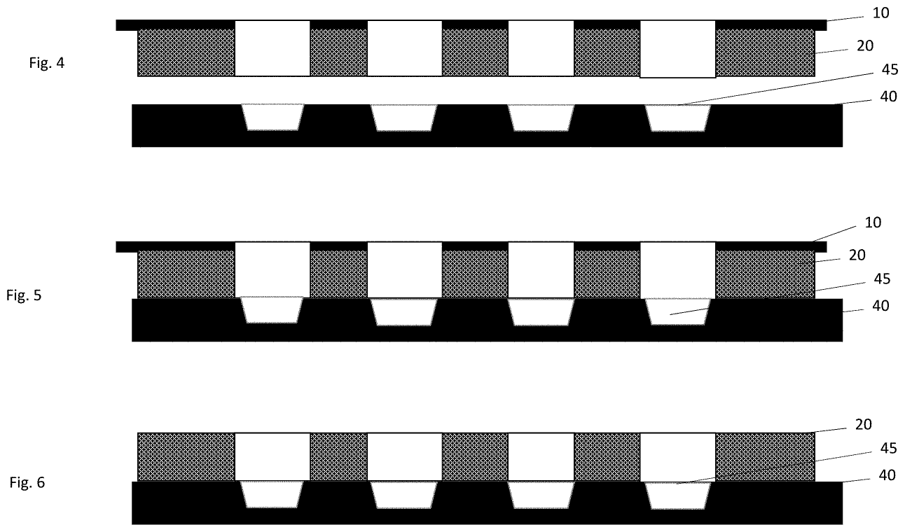

FIG. 5 is a simplified cross sectional illustration of the low cost bonding method at the fifth step, wherein the adhesive material 20 is tacked to the first substrate 40. This operation may be accomplished by raising the temperature of the adhesive structure and substrate to a modestly warm temperature about 80 to 100 degrees centigrade for example. The temperature may be sufficient to melt but not cure the adhesive. This operation may secure the adhesive structure to at least the first substrate, by tacking the adhesive material 20 to the substrate 40. In other embodiments, the heat and pressure may comprise may involve increasing the temperature of the stack to about 160 centigrade and 1.5 atmospheres.

FIG. 6 is a simplified cross sectional illustration of the low cost bonding method at the sixth step, wherein the second handling sheet, here the top handling sheet 10 is removed from the adhesive material 20. The handling sheet 10 may be removed by peeling the material away from a corner, and then over the entire surface of the adhesive structure. This operation my be done by hand or robotically, for example.

FIG. 7 is a simplified cross sectional illustration of the low cost bonding method at the seventh step, wherein a second substrate 50 is aligned against the adhesive material and the first substrate 40, with features in the second substrate 50 are registered with the through holes 25 in the adhesive material 20. The second substrate 50 may have devices 55 formed thereon. The pitch between adjacent devices 55 may be the same pitch as was formed between device cavities 45 formed in the first substrate 40. For relatively large alignment tolerances as would be used, for example, with large features and devices, this alignment may be done by hand. For more precise alignment tolerances, the alignment may be done by stepper motors and/or translation stages, for example. In any case, the through holes 25 are aligned with the location of either the devices or the device cavities that are dimensioned to accommodate the devices.

FIG. 8 is a simplified cross sectional illustration of the low cost bonding method at the eighth step, wherein the second substrate 50 is pressed against the adhesive material 20 and the first substrate 40 and bonded in place. This bonding may be done at a second, higher temperature than was the tacking shown in FIG. 6. A suitable bonding temperature may be, for example, about 140 to 170 degrees centigrade. This temperature may be sufficient to both melt and cure the adhesive material 20. The second temperature may be at least about 140 centigrade and at most about 170 centigrade, for example.

The devices 55 enclosed in the devices cavities 45 may be at least one of a MEMS device and an integrated circuit. The MEMS device 55 may have a characteristic dimension of about 300 microns. The holes may be about 50 microns larger than the characteristic dimension. The lands between the holes may be about 100 microns.

The bond formed as described above and as shown in FIG. 8 may have some interesting attributes. First and foremost, the method may be cost effective. It is estimated that the cost of this procedure would be about $400-$700, and in volume production the cost may drop to around $100. The materials cost is only about $10. This compares favourably to other wafer bonding methods which may cost around $30,000 per wafer.

The bond formed as described above may not be perfectly hermetic, that is, the environment within the device cavity may not be perfectly sealed. However, many applications can function with non-hermetic seals. Optical applications for example, need to avoid dust and moisture in the device cavity, but low pressures or perfect vacuums may not be necessary.

It is observed that this bonding methodology may be difficult to rework, as the bond is permanent and the adhesive may not be able to be uncured.

It should be understood that in the figures discussed above, similar reference numbers are intended to refer to similar structures, and the structures are illustrated at various levels of detail to give a clear view of the important features of this novel device. It should be understood that these drawings do not necessarily depict the structures to scale, and that directional designations such as “top,” “bottom,” “upper,” “lower,” “left” and “right” are arbitrary, as the device may be constructed and operated in any particular orientation In particular, it should be understood that the designations “top” and “bottom” are arbitrary designations, and may mean any two obverse surfaces on a flat wafer or substrate. The terms “wafer” and “substrate” are used interchangeably, and either refers to a surface for fabrication of a microdevice using photolithography.

A method for bonding two substrates with an adhesive material is disclosed. The method may include providing a sheet of adhesive material between two adhering handling sheets, forming through holes through the adhesive material and the adhering handling sheets, wherein the through holes are located at positions corresponding to structures formed in a first substrate and removing one of the sheets to expose a surface of the adhesive material and tacking the adhesive material to the first substrate at the exposed surface. The method may further include removing the second sheet to expose an obverse surface of the adhesive material, disposing a second substrate on the exposed obverse surface of the adhesive material to form a stack of two substrates and the adhesive material, and bonding a second substrate to the first substrate by applying heat and pressure to the stack.

Within the method, the adhesive may be a hot melt glue. The first and second substrates may be silicon substrates. In other embodiments, the substrates may be glass, ceramic, quartz, oxides, metals or other semiconductor materials. Applying heat and pressure may comprise raising the temperature of the stack to about 160 centigrade and 1.5 atmospheres. The first temperature may be at least about 80 centigrade and at most about 100 centigrade. The second temperature may be at least about 140 centigrade and at most about 170 centigrade.

The method may further comprise forming device cavities in at least one of the first or second substrate, and forming devices on the other substrate. The devices may be at least one of a MEMS device and an integrated circuit. The MEMS device may have a characteristic dimension of about 300 microns. The holes may be about 50 microns larger than the characteristic dimension. The lands between the holes may be about 100 microns. The first temperature may be at least about 80 centigrade and at most about 100 centigrade.

The handling sheet may be a waxed paper.

Also disclosed is a substrate stack, including a first substrate having a plurality of microdevices formed thereon, a second substrate having a plurality of device cavities formed thereon, and a layer of solidified, hot melt, parylene glue that adheres the first substrate to the second substrate, such that the plurality of devices are registered with and enclosed in, the plurality of device cavities.

The adhesive may be a hot melt glue. The first and second substrates may be silicon substrates.

The device may further comprise device cavities formed in at least one of the first or second substrate, and forming devices on the other substrate. The devices may be at least one of a MEMS device and an integrated circuit. The MEMS device may have a characteristic dimension of about 300 microns. The holes may be about 50 microns larger than the characteristic dimension. Lands between the holes may be about 100 microns.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Accordingly, the exemplary implementations set forth above, are intended to be illustrative, not limiting.

What is claimed is:

1. A method for bonding two substrates with an adhesive material, comprising:
providing a sheet of adhesive material between two adhering handling sheets;
forming through holes through the adhesive material and the adhering handling sheets, wherein the through holes are located at positions corresponding to structures formed in a first substrate;
removing one of the sheets to expose a surface of the adhesive material and tacking the adhesive material to the first substrate at the exposed surface;
removing the second sheet to expose an obverse surface of the adhesive material;
disposing a second substrate on the exposed obverse surface of the adhesive material to form a stack of two substrates and the adhesive material; and
bonding a second substrate to the first substrate by applying heat and pressure to the stack.

2. The method of claim 1, wherein the adhesive is a hot melt glue.

3. The method of claim 1, wherein the first and second substrates are silicon substrates.

4. The method of claim 1, wherein applying heat and pressure comprises raising the temperature of the stack to about 160 centigrade and 1.5 atmospheres.

5. The method of claim 1, wherein the first temperature is at least about 80 centigrade and at most about 100 centigrade.

6. The method of claim 1, wherein the second temperature is at least about 140 centigrade and at most about 170 centigrade.

7. The method of claim 1, further comprising forming device cavities in at least one of the first or second substrate, and forming devices on the other substrate.

8. The method of claim 7, where the devices are at least one of a MEMS device and an integrated circuit.

9. The method of claim 8, wherein the MEMS device has a characteristic dimension of about 300 microns.

10. The method of claim 9, wherein the holes are about 50 microns larger than the characteristic dimension.

11. The method of claim 10, wherein lands between the holes are about 100 microns.

12.

13. The method of claim 1, wherein the first temperature is at least about 80 centigrade and at most about 100 centigrade.

14. The method of claim 1, wherein the handling sheet comprise a waxed paper material.

15. A substrate stack, comprising:
a first substrate having a plurality of microdevices formed thereon;
a second substrate having a plurality of device cavities formed thereon;
a layer of solidified, hot melt, parylene glue that adheres the first substrate to the second substrate, such that the plurality of devices are registered with and enclosed in, the plurality of device cavities.

16. The substrate stack of claim 1, wherein the adhesive is a hot melt glue.

17. The substrate stack of claim 1, wherein the first and second substrates are silicon substrates.

18. The substrate stack of claim 1, further comprising device cavities formed in at least one of the first or second substrate, and forming devices on the other substrate.

19. The substrate stack of claim 18, where the devices are at least one of a MEMS device and an integrated circuit.

20. The substrate stack of claim 19, wherein the MEMS device has a characteristic dimension of about 300 microns.

21. The substrate stack of claim 20, wherein the holes are about 50 microns larger than the characteristic dimension.

22. The substrate stack of claim 21, wherein lands between the holes are about 100 microns.
